(19) United States
(12) Patent Application Publication
(10) Pub. No.: US 2026/0068641 A1
(43) Pub. Date: Mar. 5, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tsung-Chieh HSIAO, Changhua (TW); Chih-Lin WANG, Hsinchu (TW); Hua-An TAI, Hsinchu (TW); Yi-Huang WU, Hsinchu (TW)

(21) Appl. No.: 18/820,948

(22) Filed: Aug. 30, 2024

(51) Int. Cl. H01L 23/528; H01L 23/522; H01L 23/532; H01L 29/08

(52) U.S. Cl. CPC H01L 23/5283; H10D 62/151

(57) ABSTRACT

A semiconductor device structure, along with methods of forming such, are described. The structure includes a plurality of source/drain regions, an interconnect structure disposed over the plurality of source/drain regions, a backside interconnect structure disposed below the plurality of source/drain regions, and a first conductive feature disposed in the backside interconnect structure. The first conductive feature is electrically connected to a first number of source/drain regions of the plurality of source/drain regions. The structure further includes a second number of memory devices disposed in the backside interconnect structure, the memory devices are electrically connected to the first conductive feature, and the second number is different from the first number.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional side view of a semiconductor device structure, in accordance with some embodiments.

FIG. 2 is a cross-sectional side view of a portion of the semiconductor device structure, in accordance with some embodiments.

FIGS. 3A and 3B are cross-sectional side views of portions of the semiconductor device structure, in accordance with some embodiments.

FIGS. 4A-4D are various views of a portion of the backside interconnect structure of the semiconductor device structure, in accordance with some embodiments.

FIG. 5 is a cross-sectional side view of the semiconductor device structure, in accordance with some embodiments.

FIGS. 6A and 6B are bottom views of the semiconductor device structure, in accordance with some embodiments.

FIG. 7 is a cross-sectional side view of the semiconductor device structure, in accordance with alternative embodiments.

FIGS. 8A and 8B are bottom views of the semiconductor device structure, in accordance with alternative embodiments.

FIGS. 9A-91 are cross-sectional side views of various stages of manufacturing the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

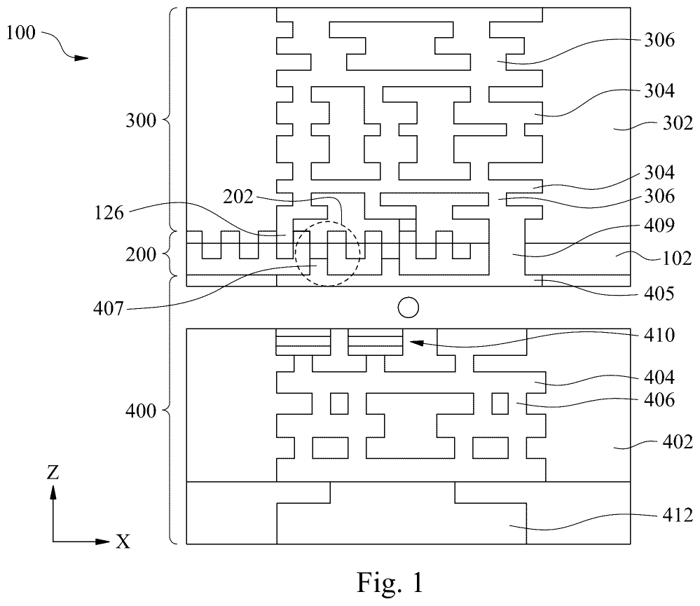

FIG. 1 illustrates a semiconductor device structure 100. As shown in FIG. 1, the semiconductor device structure 100 includes a device layer 200. The device layer 200 includes a substrate 102. The device layer 200 may include one or more devices, such as transistors, diodes, imaging sensors, resistors, capacitors, inductors, memory cells, combinations thereof, and/or other suitable devices. In some embodiments, the device layer 200 includes transistors, such as nanostructure transistors having a plurality of channels wrapped around by a gate electrode layer. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel(s) of the devices of the device layer 200 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. In some embodiments, the device layer 200 includes devices such as planar FET, FinFET, complementary FET (CFET), forksheet FET, or other suitable devices.

The semiconductor device structure 100 may further include an interconnect structure 300 disposed over the device layer 200 and the substrate 102, as shown in FIG. 1. The interconnect structure 300 may be disposed on a front side of the device layer 200. The interconnect structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnect structure 300 includes multiple levels of the conductive features 304, 306 and the conductive features 304, 306 are arranged in each level to provide electrical paths to various devices in the device layer 200 disposed below. The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a low-k dielectric material having a k value less than that of silicon oxide.

As shown in FIG. 1, in some embodiments, the semiconductor device structure 100 further includes a backside interconnect structure 400 located below the device layer 200. The backside interconnect structure 400 may be disposed on a backside of the device layer 200. The backside interconnect structure 400 includes various conductive features, such as a first plurality of conductive features 404 and second plurality of conductive features 406, and an IMD layer 402 to separate and isolate various conductive features 404, 406. In some embodiments, the first plurality of conductive features 404 are conductive lines and the second plurality of conductive features 406 are conductive vias. The backside interconnect structure 400 includes multiple levels of the conductive features 404, 406, and the conductive features 404, 406 are arranged in each level to provide electrical paths to various devices in the device layer 200 disposed above. The conductive features 404, 406 may include the same material as the conductive features 304, 306. In some embodiments, the backside interconnect structure 400 includes a redistribution layer (RDL) 412 disposed at the bottom of the backside interconnect structure 400, as shown in FIG. 1.

The backside interconnect structure 400 further includes a conductive feature 405 in contact with the backside of the device layer 200, such as in contact with a backside of the substrate 102, as shown in FIG. 1. In some embodiments, the conductive feature 405 is a power rail that is coupled to a reference voltage, positive supply voltage, or the like, and the power rail may be used to provide power to one or more devices of the device layer 200. The backside interconnect structure 400 helps to alleviate routing constraints, which in turn may increase the density of the devices in the device layer 200. Furthermore, the conductive feature 405 may have larger dimensions compared to the conductive features formed in the interconnect structure 300. As a result, one or more memory devices 410 may be formed in proximity to the conductive feature 405, and parasitic capacitance of the one or more memory devices 410 may be reduced. In some embodiments, the conductive feature 405 is connected to the devices of the device layer 200 via conductive contacts 407, as shown in FIG. 1. In some embodiments, the conductive feature 405 is connected to a conductive feature 304 of the interconnect structure 300 via a conductive feature 409, which may be a via extending through the substrate 102 and an IMD layer 302 of the interconnect structure 300, as shown in FIG. 1.

In some embodiments, one or more memory devices 410 are formed in the backside interconnect structure 400, as shown in FIG. 1. The one or more memory devices 410 may include any suitable memory devices. In some embodiments, the memory devices 410 are nonvolatile memory devices that are capable of retaining data even after power is cut off. Examples of nonvolatile memory devices include a flash memory, magnetic random-access memories (MRAMs), embedded MRAMs (eMRAMs), spin-transfer torque MRAMs (STT-MRAMs), ferroelectric random-access memories (FRAMs), resistive random-access memories (RRAMs), and phase-change random-access memories (PRAMs). In some embodiments, the memory devices 410 are MRAMs. The one or more memory devices 410 may be located below the conductive feature 405, such as one, two, or three levels below the conductive feature 405. The levels between the conductive feature 405 and the one or more memory devices 410 are represented by a dot, as shown in FIG. 1. Various arrangements of the one or more memory devices 410 relative to the conductive feature 405 are described in detail below.

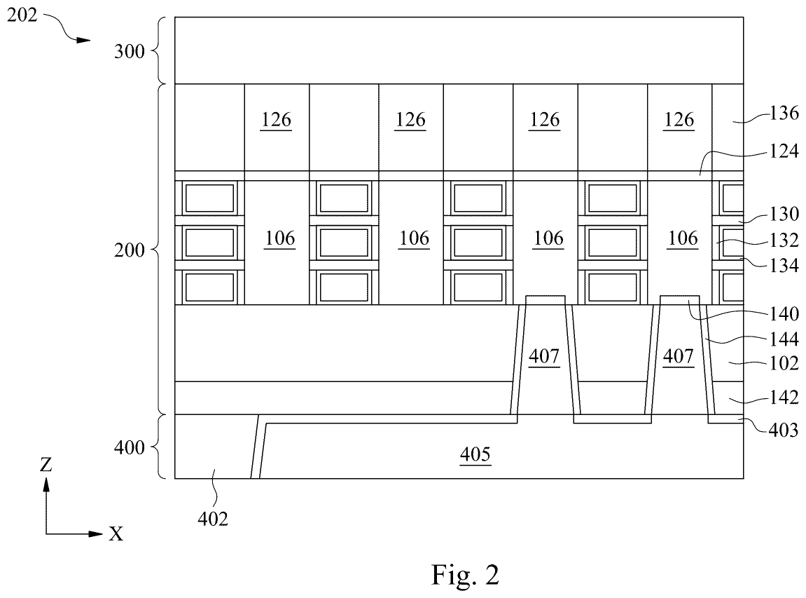

FIG. 2 is a cross-sectional side view of a portion 202 of the semiconductor device structure 100, in accordance with some embodiments. FIG. 2 illustrates an embodiment where the devices in the device layer 200 are nanostructure transistors. As shown in FIG. 2, the device layer 200 includes the substrate 102 having source/drain (S/D) regions 106 disposed thereon. The substrate 102 may be a semiconductor substrate, such as a bulk silicon substrate. In some embodiments, the substrate 102 may be an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; other suitable materials; or combinations thereof. Possible substrates 102 also include a silicon-on-insulator (SOI) substrate. SOI substrates are fabricated using separation by implantation of oxygen (SIMOX), wafer bonding, and/or other suitable methods. The S/D regions 106 may include a semiconductor material, such as Si or Ge, a III-V compound semiconductor, a II-VI compound semiconductor, or other suitable semiconductor material. Exemplary S/D regions 106 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 106 may include p-type dopants, such as boron; n-type dopants, such as phosphorus or arsenic; and/or other suitable dopants including combinations thereof. The S/D regions 106 may be formed by an epitaxial growth method using CVD, ALD or MBE. In this disclosure, a source region and a drain region are interchangeably used, and the structures thereof are substantially the same. Furthermore, source/drain region(s) may refer to a source or a drain, individually or collectively dependent upon the context.

As shown in FIG. 2, the S/D regions 106 may be connected by one or more semiconductor layers 130, which may be channels of a FET. In some embodiments, the FET is a nanostructure FET including a plurality of semiconductor layers 130, and at least a portion of each semiconductor layer 130 is wrapped around by a gate electrode layer 136. The semiconductor layer 130 may be or include materials such as Si, Ge, SiC, GeAs, GaP, InP, InAs, InSb, GaAsP, AlInAs, AlGaAs, InGaAs, GaInP, GaInAsP, or other suitable material. In some embodiments, each semiconductor layer 130 is made of Si. The number of semiconductor layers 130 arranged vertically may range from about 2 to about 6. The gate electrode layer 136 includes one or more layers of electrically conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode layer 136 includes a metal. A gate dielectric layer 134 may be disposed between the gate electrode layer 136 and the semiconductor layers 130. The gate dielectric layer 134 may include one or more layers, such as an interfacial layer and a high-k dielectric layer. In some embodiments, the interfacial layer is an oxide layer, and the high-k dielectric layer includes hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), hafnium dioxide-alumina (HfO₂—Al₂O₃) alloy, or other suitable high-k materials.

The gate dielectric layer 134 and the gate electrode layer 136 may be separated from the S/D regions 106 by inner spacers 132. The inner spacers 132 may include a dielectric material, such as SiON, SiCN, SiOC, SiOCN, or SiN. Gate spacers (not shown) may be disposed over the plurality of semiconductor layers 130. The gate spacers may include a dielectric material such as silicon oxide, silicon nitride, silicon carbide, silicon oxynitride, SiCN, silicon oxycarbide, SiOCN, and/or combinations thereof.

Conductive contacts 126 may be disposed in an ILD layer (not shown) and over the S/D regions 106, as shown in FIG. 2. The conductive contacts 126 may include one or more electrically conductive material, such as Ru, Mo, Co, Ni. W, Ti, Ta, Cu, Al, TiN and TaN. Silicide layers 124 may be disposed between the conductive contacts 126 and the S/D regions 106. The conductive contacts 126 and the gate electrode layers 136 are electrically isolated by the gate spacers (not shown).

In some embodiments, as shown in FIG. 2, a hard mask layer 142 is formed on a back surface of the substrate 102, and conductive contacts 407 is formed in the substrate 102 and the hard mask layer 142. In some embodiments, the substrate 102 is thinned down from the backside before forming the hard mask layer 142. The hard mask layer 142 may include any suitable material. In some embodiments, the hard mask layer 142 includes a dielectric material, such as SiN, SiCN, SiOCN, SiON, or other suitable dielectric material. The conductive contact 407 includes an electrically conductive material, such as Co, W, Ru, Mo, Cu, or other suitable material. In some embodiments, liners 144 may be formed on side surfaces of each conductive contact 407. Each liner 144 may include SiN, SiCN, SiOCN, SiON, or other suitable material. In some embodiments, the liners 144 include the same material as the hard mask layer 142. In some embodiments, the liners 144 are formed by first forming a conformal layer in openings formed in the hard mask layer 142 and the substrate 102, followed by an anisotropic etch process to remove horizontal portions of the conformal layer to form the liners 144 on the side surfaces of the hard mask layer 142 and the substrate 102. As shown in FIG. 2, in some embodiments, a silicide layer 140 is formed between each conductive contact 407 and a corresponding S/D region 106. The silicide layer 140 may include TiSi, CoSi, NiSi, TiNiSi, or other suitable material.

As shown in FIG. 2, the backside interconnect structure 400 includes the IMD layer 402 and the conductive feature 405. In some embodiments, a barrier layer 403 is disposed between the conductive feature 405 and the IMD layer 402 and between the conductive feature 405 and the hard mask layer 142, as shown in FIG. 2. The barrier layer 403 serves to prevent the metal diffusion from the conductive feature 405 to the hard mask layer 142 and the IMD layer 402. In some embodiments, the conductive feature 405 includes a material that is not susceptible to diffusion, and the barrier layer 403 is not used. In some embodiments, the barrier layer 403 is selectively formed on the dielectric materials of the IMD layer 402 and the hard mask layer 142. The barrier layer 403 may include TiN, TaN, Ru, Co, or other suitable material. The barrier layer 403 may be formed by a conformal process, such as ALD.

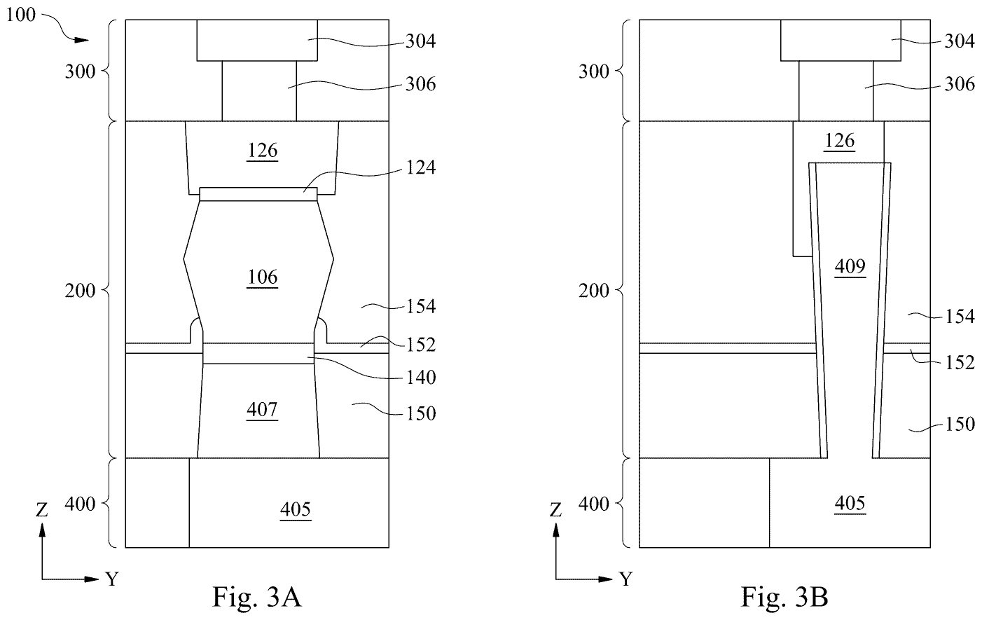

FIGS. 3A and 3B are cross-sectional side views of portions of the semiconductor device structure 100, in accordance with some embodiments. FIGS. 3A and 3B illustrate YZ plane of the portions of the semiconductor device structure 100, in accordance with some embodiments. In some embodiments, the substrate 102 is removed during the backside processing. As shown in FIG. 3A, in some embodiments, the conductive contacts 126 and the silicide layers 124 are formed on the front side of the S/D regions 106, and the conductive contacts 407 and the silicide layers 140 are formed on the backside of the S/D regions 106. In some embodiments, an isolation region 150, such as a shallow trench isolate (STI), is disposed around the conductive contacts 407, as shown in FIG. 3A.

In some embodiments, the conductive feature 405 is electrically connected to the conductive features 304, 306 located in the interconnect structure 300 via the S/D region 106, as shown in FIG. 3A. In some embodiments, in the regions where the S/D region 106 is not present, the conductive feature 405 may be electrically connected to the conductive features 304, 306 located in the interconnect structure 300 via the conductive feature 409, as shown in FIG. 3B. The conductive feature 409 may be a conductive via and may extend through the isolation region 150 and into the ILD 154. In some embodiments, the conductive feature 409 extends into the conductive contact 126, as shown in FIG. 3B.

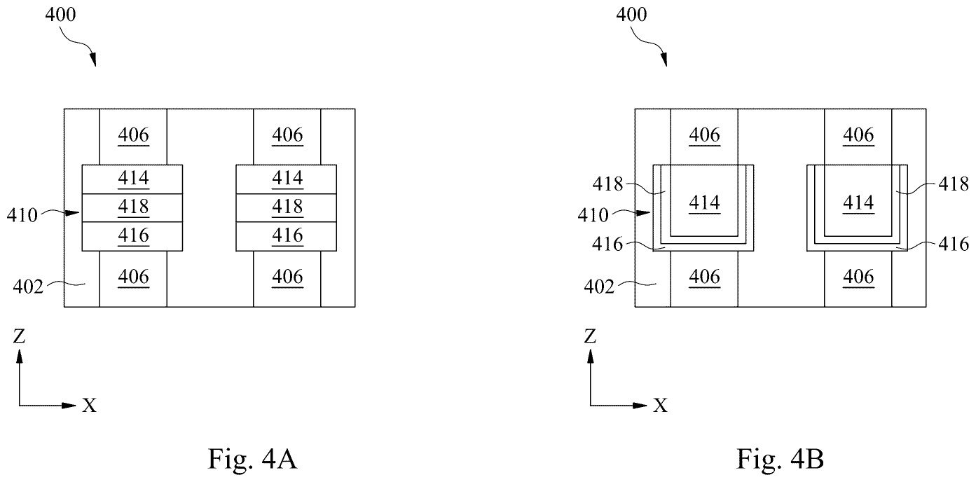

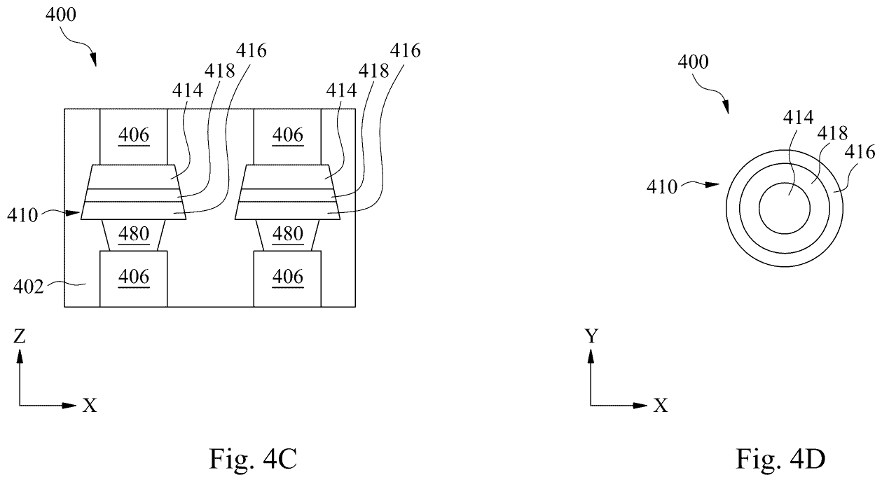

FIGS. 4A-4D are various views of a portion of the backside interconnect structure 400 of the semiconductor device structure 100, in accordance with some embodiments. FIG. 4A is a cross-sectional view of the portion of the backside interconnect structure 400 of the semiconductor device structure 100. As shown in FIG. 4A, the backside interconnect structure 400 includes the one or more memory devices 410. In some embodiments, the memory devices 410 are MRAM cells, and each MRAM cell includes a top electrode layer 414, a bottom electrode layer 416, and a magnetic tunnel junction (MTJ) layer 418 disposed between the top electrode layer 414 and the bottom electrode layer 416. The top electrode layer 414 and the bottom electrode layer 416 may each include an electrically conductive material, such as TiN, TaN, Cu, Co, W, Ag, Al, Ru, AlCu, Mo, or combinations thereof.

The MTJ layer 418 is deposited in a form of multiple material stacks (not illustrated in FIG. 4A) over the bottom electrode layer 416. In some embodiments, the MTJ layer 418 includes a lower ferromagnetic electrode and an upper ferromagnetic electrode, which are separated from one another by a tunneling barrier layer. In some embodiments, the lower ferromagnetic electrode may have a fixed or “pinned” magnetic orientation, while the upper ferromagnetic electrode has a variable or “free” magnetic orientation, which may be switched between two or more distinct magnetic polarities that each represents a different data state, such as a different binary state. In other implementations, however, the MTJ layer 418 may be vertically “flipped”, such that the lower ferromagnetic electrode has a “free” magnetic orientation, while the upper ferromagnetic electrode has a “pinned” magnetic orientation.

In some embodiments, the upper and lower ferromagnetic electrodes each includes or is made from iron, cobalt, nickel, iron cobalt, nickel cobalt, cobalt iron boride, iron boride, iron platinum, iron palladium, or the like. In some embodiments, the tunneling barrier layer provides electrical isolation between the upper ferromagnetic electrode and the lower ferromagnetic electrode, while still allowing electrons to tunnel through the tunneling barrier layer under proper conditions. The tunneling barrier layer may include or be made of magnesium oxide (MgO), aluminum oxide (e.g., Al₂O₃), nickel oxide, gadolinium oxide, tantalum oxide, molybdenum oxide, titanium oxide, tungsten oxide, or the like. In some embodiments, the tunneling barrier layer may include non-ferromagnetic metal, for example, Ag, Au, Cu, Ta, W, Mn, Pt, Pd, V, Cr, Nb, Mo, Tc, Ru or the like.

In some embodiments, the one or more memory devices 410 are RRAMs, and the MTJ layer 418 is a resistive layer, such as a layer of TaO. The top electrode layer 414 may be an Ir layer, and the bottom electrode layer 416 may be a Ta layer. In some embodiments, the top electrode layer 414 has a thickness ranging from about 5 nm to about 10 nm, the bottom electrode layer 416 has a thickness ranging from about 10 nm to about 30 nm, and the resistive layer has a thickness ranging from about 15 nm to about 30 nm.

FIG. 4A illustrates planar type MRAM cells, and FIG. 4B illustrates vertical type MRAM cells. FIG. 4B is a cross-sectional view of the portion of the backside interconnect structure 400 of the semiconductor device structure 100. As shown in FIG. 4B, the bottom electrode layer 416 is formed in an opening and has an “U” shaped cross-section profile. The MTJ layer 418 is formed on the bottom electrode layer 416 and also has an “U” shaped cross-section profile. The top electrode 414 is formed on the MTJ layer 418 and has three sides surrounded by the MTJ layer 418 and the bottom electrode layer 416, as shown in FIG. 4B.

FIG. 4C is a cross-sectional view of the portion of the backside interconnect structure 400 of the semiconductor device structure 100. As shown in FIG. 4C, in some embodiments, the one or more memory devices 410 each has a trapezoidal cross-sectional shape. In some embodiments, the top electrode layer 414 has a first width along the X direction, the MTJ layer 418 has a second width along the X direction, and the bottom electrode layer 416 has a third width along the X direction. In some embodiments, the third width is greater than the second width, and the second width is greater than the first width. In some embodiments, each memory device 410 includes a bottom electrode via (BEVA) 480. The BEVA 480 may include the same or different material as the bottom electrode layer 416. In some embodiments, the bottom electrode layer 146 includes a layer of TaN and a layer of TiN, and the BEVA 480 includes TiN. In some embodiments, the MTJ 418 includes a first ferromagnetic layer, a second ferromagnetic layer disposed on the first ferromagnetic layer, a third ferromagnetic layer disposed on the second ferromagnetic layer, a first tunnel barrier layer disposed on the third ferromagnetic layer, a fourth ferromagnetic layer disposed on the first tunnel barrier layer, a second tunnel barrier layer disposed on the fourth ferromagnetic layer, and a cap layer disposed on the second tunnel barrier layer. In some embodiments, the first ferromagnetic layer includes NiCr, the second ferromagnetic layer includes CoIr, the third ferromagnetic layer includes CoFeB, the first tunnel barrier layer includes MgO, the fourth ferromagnetic layer includes CoFeB, the second tunnel barrier layer includes MgO, and the cap layer includes Ru.

In some embodiments, the BEVA 480 has a thickness ranging from about 35 nm to about 60 nm, the bottom electrode layer 416 has a thickness ranging from about 15 nm to about 45 nm, and the top electrode layer 414 has a thickness ranging from about 15 nm to about 45 nm. In some embodiments, the first ferromagnetic layer has a thickness ranging from about 3 nm to about 7 nm, the second ferromagnetic layer has a thickness ranging from about 1 nm to about 3 nm, the third ferromagnetic layer has a thickness ranging from about 1 nm to about 2 nm, the first tunnel barrier layer has a thickness ranging from about 0.5 nm to about 1.5 nm, the fourth ferromagnetic layer has a thickness ranging from about 1 nm to about 3 nm, the second tunnel barrier layer has a thickness ranging from about 0.5 nm to about 1.5 nm, and the cap layer has a thickness 5 nm to about 15 nm.

In some embodiments, the MTJ 418 includes a first ferromagnetic layer, a second ferromagnetic layer disposed on the first ferromagnetic layer, a first coupling layer disposed on the second ferromagnetic layer, a third ferromagnetic layer disposed on the first coupling layer, a second coupling layer disposed on the third ferromagnetic layer, a fourth ferromagnetic layer disposed on the second coupling layer, a first tunnel barrier layer disposed on the third ferromagnetic layer, a fifth ferromagnetic layer disposed on the first tunnel barrier layer, a second tunnel barrier layer disposed on the fifth ferromagnetic layer, and a cap layer disposed on the second tunnel barrier layer. In some embodiments, the first ferromagnetic layer includes NiCr, the second ferromagnetic layer includes CoPt, the first coupling layer includes Ru, the third ferromagnetic layer includes CoPt, the second coupling layer includes TaCo, the fourth ferromagnetic layer includes CoFeB, the first tunnel barrier layer includes MgO, the fifth ferromagnetic layer includes CoFeB, the second tunnel barrier layer includes MgO, and the cap layer includes Ru. In some embodiments, the first ferromagnetic layer has a thickness ranging from about 3 nm to about 7 nm, the second ferromagnetic layer has a thickness ranging from about 3 nm to about 7 nm, the first coupling layer has a thickness ranging from about 0.2 nm to about 1 nm, the third ferromagnetic layer has a thickness ranging from about 1.5 nm to about 3.5 nm, the second coupling layer has a thickness ranging from about 0.5 nm to about 1.5 nm, the fourth ferromagnetic layer has a thickness ranging from about 0.5 nm to about 1.5 nm, the first tunnel barrier layer has a thickness ranging from about 0.5 nm to about 1.5 nm, the fifth ferromagnetic layer has a thickness ranging from about 1 nm to about 3 nm, the second tunnel barrier layer has a thickness ranging from about 0.5 nm to about 1.5 nm, and the cap layer has a thickness 1 nm to about 3 nm.

FIG. 4D is a top view of the memory device 410. In some embodiments, the top electrode layer 414 has a first shape when viewed from the top, the MTJ layer 418 has a second shape when viewed from the top, and the bottom electrode layer 416 has a third shape when viewed from the top. In some embodiments, the first, second, and third shapes are the same. For example, the first, second, and third shapes are all circular, as shown in FIG. 4D. In some embodiments, the first, second, and third shapes are all rectangular. In some embodiments, the first, second, and third shapes are different. For example, the first shape may be circular, the second shape may be circular, and the third shape may be rectangular. As shown in FIG. 4D, in some embodiments, the diameter of the top electrode layer 414 is smaller than the diameter of the MTJ layer 418, which is smaller than the diameter of the bottom electrode layer 416.

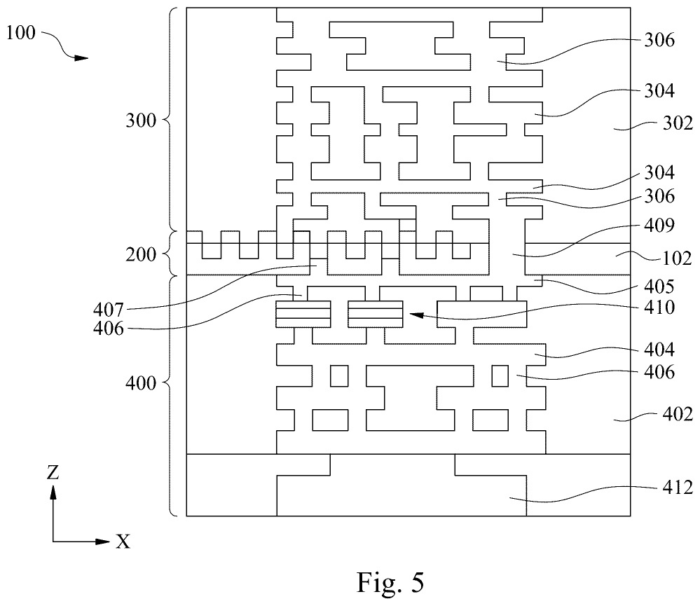

FIG. 5 is a cross-sectional side view of the semiconductor device structure 100, in accordance with some embodiments. In some embodiments, the one or more memory devices 410 are located in an IMD layer 402 that is one level below the conductive feature 405, as shown in FIG. 5. In other words, a single IMD layer 402 is disposed between the one or more memory devices 410 and the conductive feature 405, and conductive features 406, or conductive vias, are disposed in the single IMD layer 402 to electrically connecting the one or more memory devices 410 and the conductive feature 405. In some embodiments, as described above, the dimensions of the conductive feature 405 are enlarged as a result of being located on the backside of the device layer 200. The enlarged conductive feature 405 may be electrically connected to multiple memory devices 410. Furthermore, the enlarged conductive feature 405 may enable various arrangements of the memory devices 410 with reduced parasitic capacitance. For example, in some embodiments, the memory devices 410 are not vertically aligned (along the Z direction) with the S/D regions 106 of the devices in the device layer 200. In such embodiments, the memory devices 410 would not be visible in the plane shown in FIG. 5.

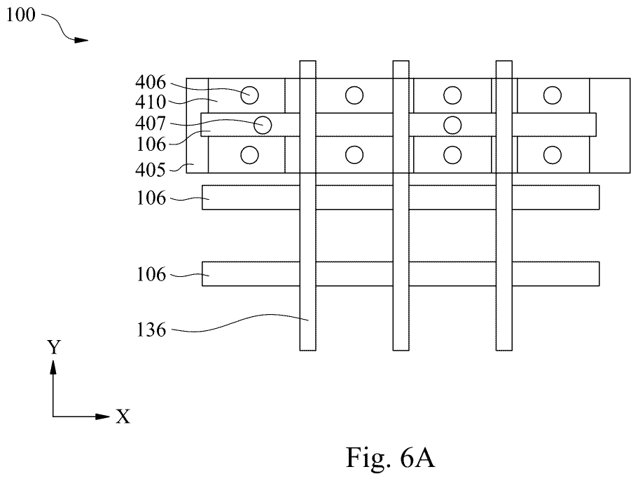

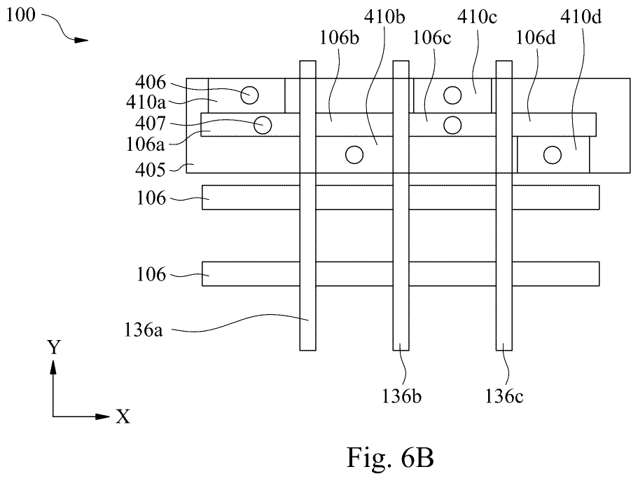

FIGS. 6A and 6B are bottom views of the semiconductor device structure 100, in accordance with some embodiments. FIGS. 6A and 6B illustrate the S/D regions 106, the gate electrode layer 136, the conductive feature 405, the memory devices 410, the conductive contacts 407 connecting the S/D regions 106 and the conductive feature 405, and the conductive features 406 connecting the conductive feature 405 and the memory devices 410. Other components of the semiconductor device structure 100 are omitted for clarity.

As shown in FIG. 6A, the S/D regions 106 are formed on opposite sides of the gate electrode layer 136. The conductive feature 405 is disposed below the S/D regions 106 and the gate electrode layers 136. As shown in FIG. 6A, the conductive feature 405 may include a width along the Y direction substantially greater than a width of the S/D region 106 along the Y direction. The width of the S/D region 106 may be varied due to the facets, as shown in FIG. 3A. In some embodiments, the width of the conductive feature 405 may be greater than the largest width of the S/D region 106. In some embodiments, the S/D regions 106 are formed from a fin structure, and the width of the conductive feature 405 is substantially greater than a width of the fin structure. As shown in FIG. 6A, the conductive feature 405 laterally extends to a region between adjacent fin structures. Thus, the conductive feature 405 would not interfere with the conductive features 404, 406 electrically connected to the S/D regions 106 located in the adjacent fin structure.

In embodiments where a power rail is formed on the front side of the device layer 200, the power rail may have the same width as the fin structure due to metal routing limitation. The power rail located on the front side of the device layer 200 may be electrically connected to a number of source regions and a number of memory devices. Because of the small width of the front side power rail, the number of memory devices connected to the front side power rail cannot exceed the number of source regions connected to the front side power rail. For example, the front side power rail is electrically connected to two source regions, and a maximum of two memory devices are electrically connected to the front side power rail.

With the enlarged conductive feature 405 located on the backside of the device layer 200, the number of memory devices 410 electrically connected to the conductive feature 405 may be substantially greater than the number of source regions electrically connected to the conductive feature 405. Furthermore, the memory devices 410 electrically connected to the conductive feature 405 may be arranged in ways to minimized parasitic capacitance. As shown in FIG. 6A, multiple memory devices 410 are disposed under the conductive feature 405. The memory devices 410 are arranged spaced apart and are not disposed directly under the S/D regions 106 in order to reduce parasitic capacitance. In other words, the memory devices 410 are misaligned with the S/D regions 106 along the Z direction. The term “misaligned” is referring to the special relationship along the Z direction between a memory device 410 and a S/D region 106 that is electrically connected to the memory device 410, and the term “misaligned” is defined as a centerline of the memory device 410 being outside of planes defined by outside edges of the S/D region 106. In some embodiments, the memory device 410 is completely offset from the S/D region 106 that the memory device 410 is electrically connected to. For example, the memory device 410 and the electrically connected S/D region 106 do not overlap along the Z direction. As shown in FIG. 6A, in some embodiments, the conductive feature 405 is electrically connected to two source regions 106 via corresponding conductive contacts 407 and eight memory devices 410 via corresponding conductive features 406. Thus, the number of the memory devices 410 electrically connected to the conductive feature 405 is at least two times the number of source regions 106 electrically connected to the conductive feature 405, such as about four times the number of source regions 106. In some embodiments, the conductive feature 405 cannot electrically connect to both the source region 106 and the drain region 106 of the same transistor. The memory devices 410 are spaced apart to reduce parasitic capacitance. For example, as shown in FIG. 6A, the S/D region 106 (or the fin structure) is between the adjacent memory devices 410 along the Y direction when viewed from the bottom, and the gate electrode layer 136 is between the adjacent memory devices 410 along the X direction when viewed from the bottom.

In some embodiments, as shown in FIG. 6B, the number of memory devices 410 electrically connected to the conductive feature 405 is about two times the number of source regions 106 electrically connected to the conductive feature 405 in order to further reduce parasitic capacitance. In some embodiments, the semiconductor device structure 100 includes a first gate electrode layer 136a, a second gate electrode layer 136b disposed adjacent the first gate electrode layer 136a, and a third gate electrode layer 136c disposed adjacent the second gate electrode layer 136b, as shown in FIG. 6B. A first source region 106a is disposed on a first side of the first gate electrode layer 136a, a first drain region 106b is disposed on a second side opposite the first side of the first gate electrode layer 136a. The first drain region 106b is also disposed on a first side of the second gate electrode layer 136b, and a second source region 106c is disposed on a second side opposite the first side of the second gate electrode layer 136b. The second source region 106c is also disposed on a first side of the third gate electrode layer 136c, and a second drain region 106d is disposed on a second side opposite the first side of the third gate electrode layer 136c. The first source region 106a has a first side and a second side opposite the first side, the first drain region 106b has a first side and a second side opposite the first side, the second source region 106c has a first side and a second side opposite the first side, and the second drain region 106d has a first side and a second side opposite the first side. The first sides and the second sides of the first, second source regions 106a, 106c and the first, second drain regions 106b, 106d are oriented in a direction substantially perpendicular to the orientation of the first and second sides of the first, second, and third gate electrode layers 136a, 136b, 136c. Furthermore, the first sides of the first, second source regions 106a, 106c and first, second drain regions 106b, 106d are substantially aligned along the X direction, and the second sides of the first, second source regions 106a, 106c and first, second drain regions 106b, 106d are substantially aligned along the X direction. In some embodiments, as shown in FIG. 6B, the conductive feature 405 is electrically connected to a first memory device 410a, a second memory device 410b, a third memory device 410c, and a fourth memory device 410d. The first memory device 410a is disposed on the first side of the first source region 106a, the second memory device 410b is disposed on the second side of the first drain region 106b, the third memory device 410c is disposed on the first side of the second source region 106c, and the fourth memory device 410d is disposed on the second side of the second drain region 106d. With such arrangements of the memory devices 410a-d, parasitic capacitance is minimized.

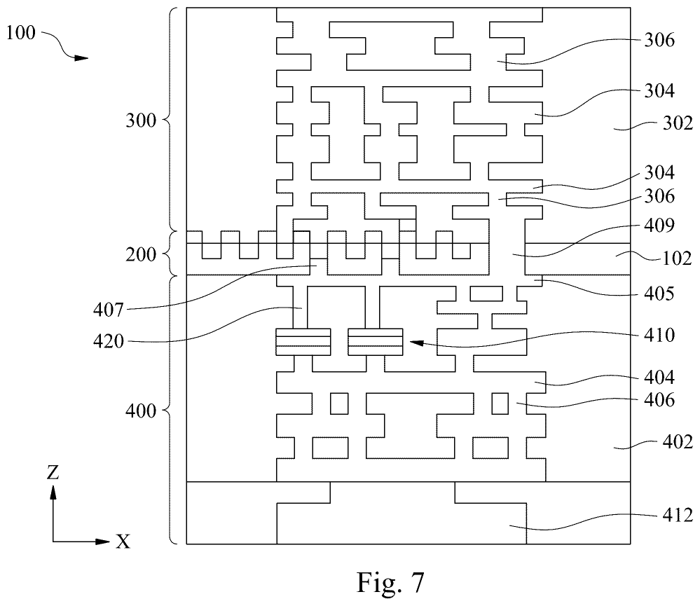

FIG. 7 is a cross-sectional side view of the semiconductor device structure 100, in accordance with alternative embodiments. In some embodiments, the one or more memory devices 410 are located in an IMD layer 402 that is two or more levels below the conductive feature 405, as shown in FIG. 7. In other words, two or more IMD layers 402 are disposed between the one or more memory devices 410 and the conductive feature 405. In some embodiments, instead of using the conductive features 404, 406, conductive features 420 are formed in the two or more IMD layers 402 to electrically connect the conductive feature 405 and the memory devices 410. As shown in FIG. 7, in some embodiments, one conductive feature 420 is in contact with the conductive feature 405 and one of the memory devices 410. Compared to the conductive features 404, 406, the single conductive feature 420 has reduced electrical resistance. In some embodiments, the conductive feature 420 is a super via that extends through multiple IMD layers 402.

In some embodiments, as shown in FIG. 7, a memory device 410 and a conductive feature 404 are disposed in the same IMD layer 402, and the conductive feature 405 is disposed directly above the conductive feature 404 and the memory device 410. In some embodiments, three IMD layers 402 are disposed between the memory device 410 and the conductive feature 405 and between the conductive feature 404 and the conductive feature 405. A single conductive feature 420 is disposed in the three IMD layers 402 to electrically connect the conductive feature 405 and the memory device 410. Multiple conductive features 404, 406 are disposed in the three IMD layers 402 to electrically connect the conductive feature 405 and the conductive feature 404, as shown in FIG. 7.

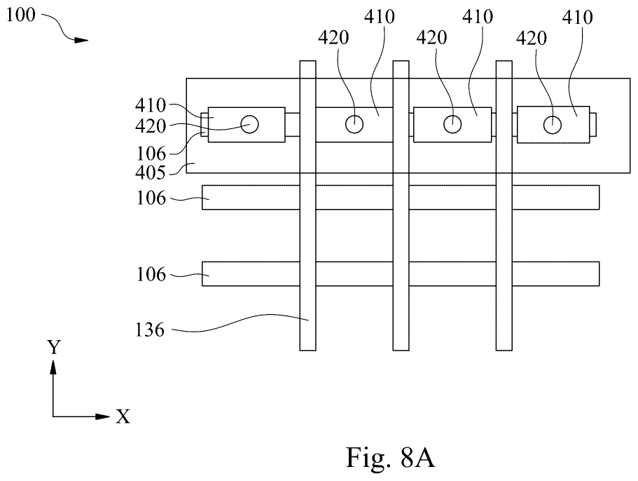

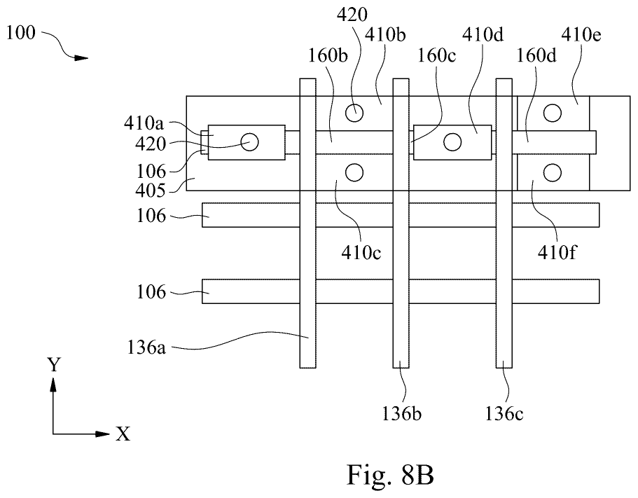

FIGS. 8A and 8B are bottom views of the semiconductor device structure 100, in accordance with alternative embodiments. FIGS. 8A and 8B illustrate the S/D regions 106, the gate electrode layer 136, the conductive feature 405, the memory devices 410, and the conductive features 420 connecting the conductive feature 405 and the memory devices 410. Other components of the semiconductor device structure 100 are omitted for clarity. In some embodiments, because the memory devices 410 are located multiple levels below the S/D regions 106, the memory devices 410 may be disposed directly below the S/D regions 106 without having increased parasitic capacitance. As shown in FIG. 8A, four memory devices 410 are disposed directly below four S/D regions 106. Of the four S/D regions 106, two are source regions 106, and the other two are drain regions 106. In some embodiments, the two source regions 106 are electrically connected to the conductive feature 405 via the conductive contacts 407 (FIG. 7), and the conductive feature 405 is electrically connected to four memory devices via the conductive features 420. Thus, the number of memory devices 410 electrically connected to the conductive feature 405 is still at least two times the number of source regions 106 electrically connected to the conductive feature 405. Furthermore, adjacent memory devices 410 are spaced apart by at least the width of the gate electrode layer 136, which further reduces parasitic capacitance.

In some embodiments, the memory devices 410 are aligned along the X direction, as shown in FIG. 8A. In some embodiments, the memory devices 410 are offset along the X direction, so more memory devices 410 can be placed under the conductive feature 405, as shown in FIG. 8B. In some embodiments, the semiconductor device structure 100 includes a first gate electrode layer 136a, a second gate electrode layer 136b disposed adjacent the first gate electrode layer 136a, and a third gate electrode layer 136c disposed adjacent the second gate electrode layer 136b, as shown in FIG. 8B. A first source region 106a is disposed on a first side of the first gate electrode layer 136a, a first drain region 106b is disposed on a second side opposite the first side of the first gate electrode layer 136a. The first drain region 106b is also disposed on a first side of the second gate electrode layer 136b, and a second source region 106c is disposed on a second side opposite the first side of the second gate electrode layer 136b. The second source region 106c is also disposed on a first side of the third gate electrode layer 136c, and a second drain region 106d is disposed on a second side opposite the first side of the third gate electrode layer 136c. In some embodiments, as shown in FIG. 8B, the conductive feature 405 is electrically connected to a first memory device 410a, a second memory device 410b, a third memory device 410c, a fourth memory device 410d, a fifth memory device 410e, and a sixth memory device 410f. The first memory device 410a is disposed directly below the first source region 106a. The second and third memory devices 410b, 410c are disposed between the first and second gate electrode layers 136 when viewed from the bottom, and the first drain region 106b is disposed between the second and third memory devices 410b, 410c when viewed from the bottom. The fourth memory device 410d is disposed directly below the second source region 106c. The fifth and sixth memory devices 410e, 410f are disposed between the second and third gate electrode layers 136 when viewed from the bottom, and the second drain region 106d is disposed between the fifth and sixth memory devices 410e, 410f when viewed from the bottom. With such arrangements of the memory devices 410a-f, parasitic capacitance is minimized.

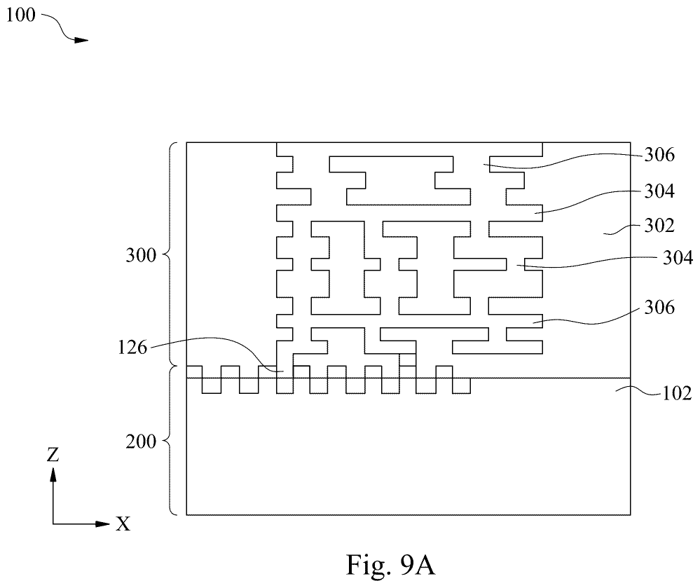

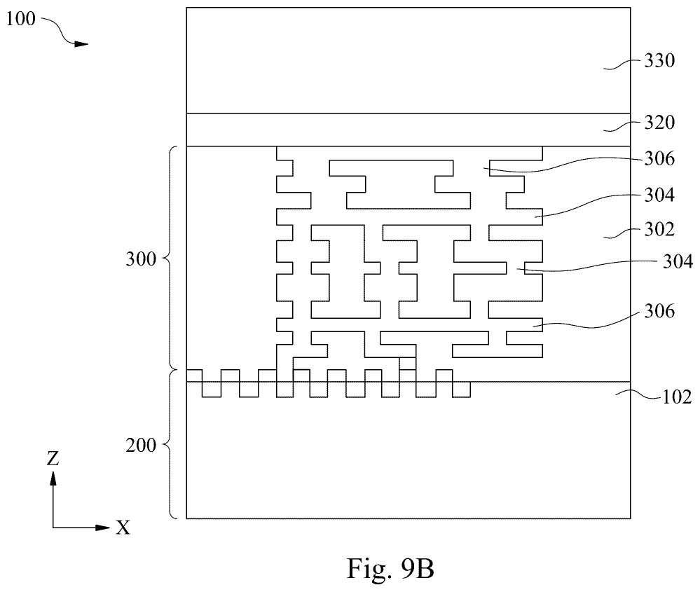

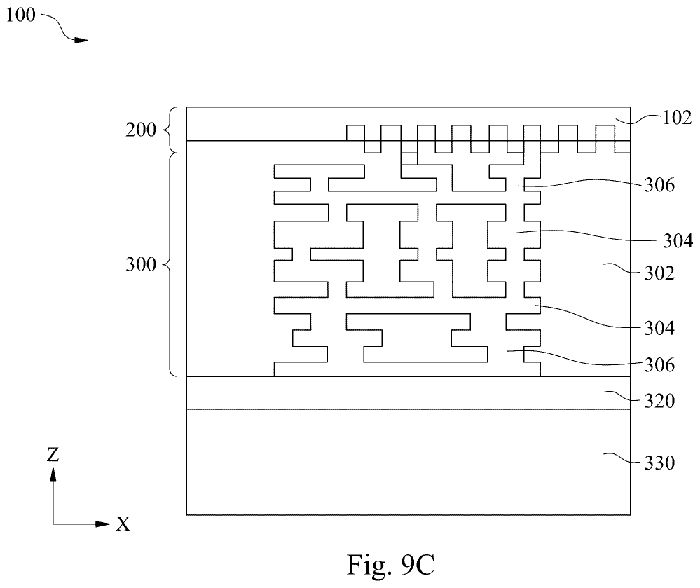

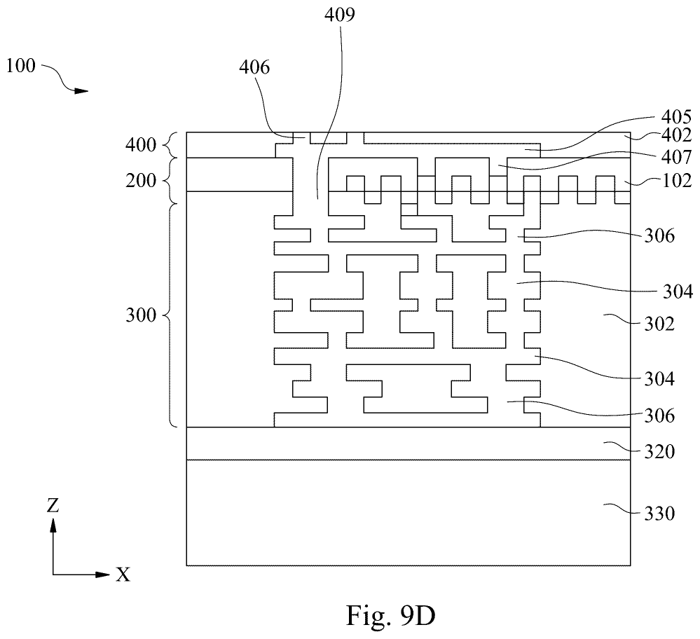

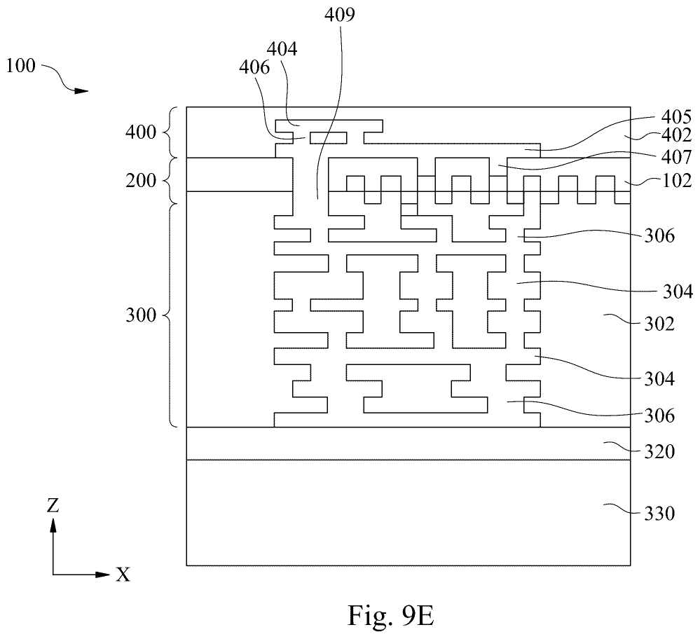

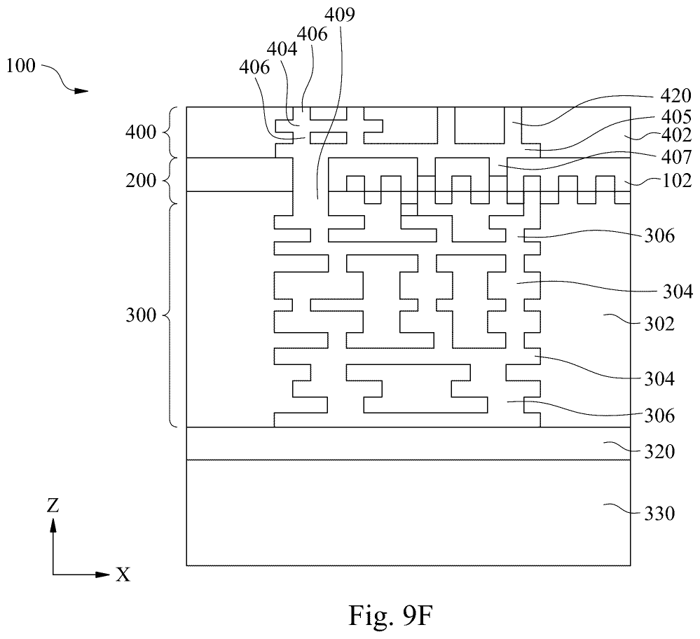

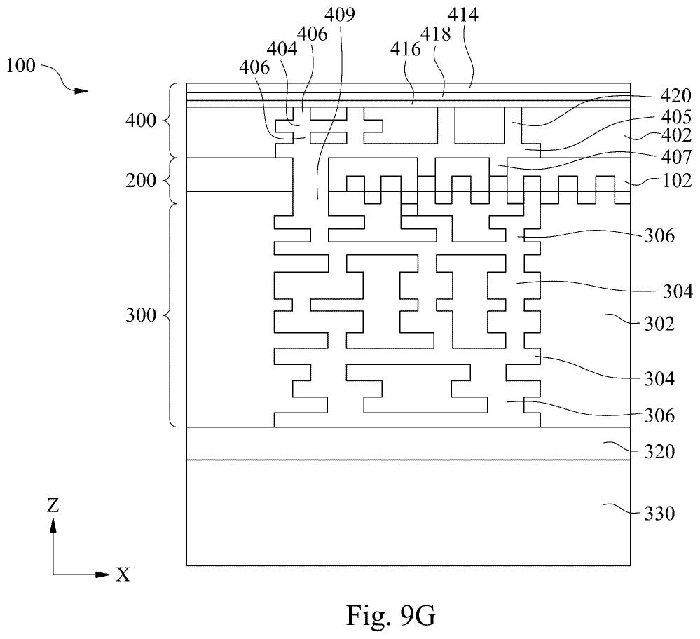

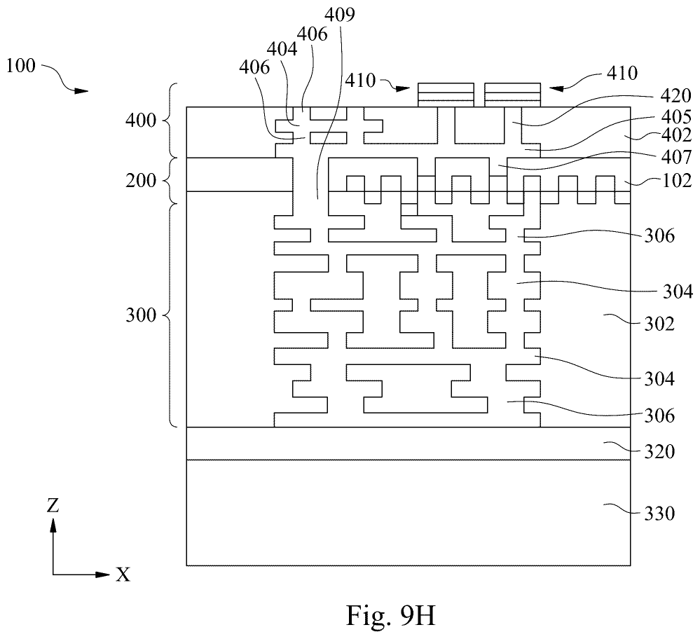

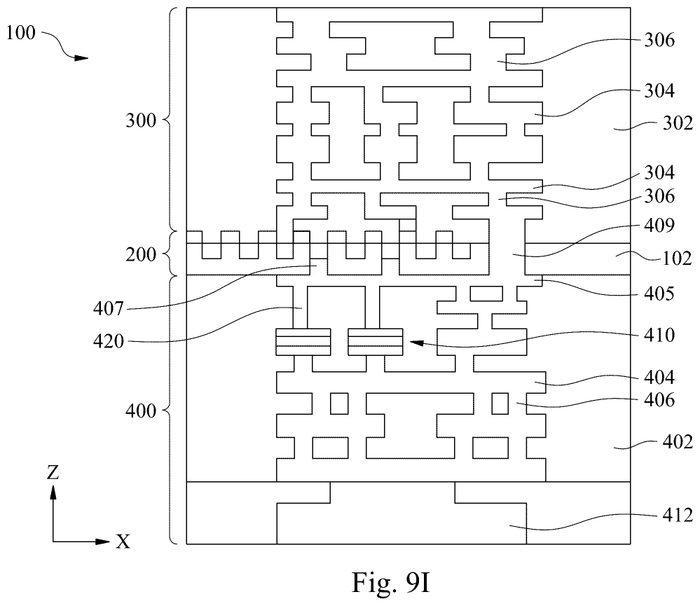

FIGS. 9A-91 are cross-sectional side views of various stages of manufacturing the semiconductor device structure 100, in accordance with some embodiments. As shown in FIG. 9A, a plurality of devices are formed on the substrate 102 to form the device layer 200, and the interconnect structure 300 are formed over the device layer 200. The processes to form the device layer 200 may be referred to as front-end-of-line (FEOL) processes, and the processes to form the interconnect structure 300 may be referred to as back-end-of-line (BEOL) processes. In some embodiments, the processes to form the conductive contacts 126 are referred to as middle-of-line (MOL) processes.

Next, as shown in FIG. 9B, a bonding layer 320 and a carrier wafer 330 are formed over the interconnect structure 300. The semiconductor device structure 100 is then flipped over for backside processing. As shown in FIG. 9C, the substrate 102 is thinned or removed. Next, as shown in FIG. 9D, the conductive feature 409 is formed through the substrate 102 and a portion of the IMD layer 302 to be in contact with a conductive feature 304 formed in the interconnect structure 300. The conductive contacts 407 are formed through the substrate 102 to be electrically connected to the source regions 106 (or drain regions 106). The conductive feature 405 is formed on the back surface of the substrate 102 (or a back surface of a dielectric material that replaced the substrate 102), and the conductive feature 405 is electrically connected to the conductive feature 409 and the conductive contacts 407. The IMD layers 402 are formed over the substrate 102, and conductive features 406 are formed over the conductive feature 405. As shown in FIG. 9E, a conductive feature 404 is formed on the conductive features 406, and another IMD layer 402 is formed on the conductive feature 404. At this stage, three IMD layers 402 are formed over the conductive feature 405. In a first region over the conductive feature 405, conductive features 404, 406 are formed in the lower two of the three IMD layers 402, while no conductive features are formed in the top layer of the three IMD layers 402, as shown in FIG. 9E. In a second region over the conductive feature 405, no conductive features are formed in the three IMD layers 402.

Next, as shown in FIG. 9F, conductive features 406 are formed in the first region over the conductive feature 405, and conductive features 420 are formed in the second region over the conductive feature 405. The conductive features 406 and conductive features 420 may be formed by first forming openings in the first and second regions over the conductive feature 405. The openings formed in the first region are shallower than the openings formed in the second region, because the conductive feature 404 formed in the first region may function as an etch stop layer. Next, a conductive material is formed in the openings in the first and second regions over the conductive feature 405 to form the conductive features 406 and the conductive features 420. A planarization process is performed to remove portions of the conductive material formed on the IMD layer 402.

As shown in FIG. 9G, the bottom electrode layer 416, the MTJ layer 418, and the top electrode layer 414 are sequentially deposited over the IMD layer 402, the conductive features 406, and the conductive features 420. Next, the bottom electrode layer 416, the MTJ layer 418, and the top electrode layer 414 are patterned to form the memory devices 410, as shown in FIG. 9H. The memory devices 410 may be planar type MRAMs. In some embodiments, vertical type MRAMS may be formed. For example, an IMD layer 402 is formed on the conductive features 406, 420, openings are formed in the IMD layer 402, and the bottom electrode layer 416, the MTJ layer 418, and the top electrode layer 414 are formed in the openings to form the vertical type MRAMs. The memory devices 410 may be arranged as shown in FIGS. 8A and 8B.

In some embodiments, the memory devices 410 are formed in a similar fashion one level over the conductive feature 405, and the memory devices 410 may be arranged as shown in FIGS. 6A and 6B.

Next, as shown in FIG. 9I, the backside interconnect structure 400 is completed, the semiconductor device structure 100 is flipped over so the interconnect structure 300 is disposed over the backside interconnect structure 400, and the carrier wafer 330 and the bonding layer 320 are removed.

The present disclosure in various embodiments provides semiconductor device structure 100 including a conductive feature 405 and memory devices 410 disposed in a backside interconnect structure 400. Some embodiments may achieve advantages. For example, because the conductive feature 405 is formed in the backside interconnect structure 400, the size of the conductive feature 405 is enlarged due to less routing constraint. The larger conductive feature 405 may enable more memory devices 410 to be electrically connected to the conductive feature 405 with reduced parasitic capacitance.

An embodiment is a semiconductor device structure. The structure includes a plurality of source/drain regions, an interconnect structure disposed over the plurality of source/drain regions, a backside interconnect structure disposed below the plurality of source/drain regions, and a first conductive feature disposed in the backside interconnect structure. The first conductive feature is electrically connected to a first number of source/drain regions of the plurality of source/drain regions. The structure further includes a second number of memory devices disposed in the backside interconnect structure, the memory devices are electrically connected to the first conductive feature, and the second number is different from the first number.

Another embodiment is a semiconductor device structure. The structure includes a first source/drain region disposed over a substrate, and the first source/drain region has a first width. The structure further includes an interconnect structure disposed over the first source/drain region and a first conductive feature disposed below a backside of the substrate. The first conductive feature has a second width substantially greater than the first width, and the first conductive feature is electrically connected to the first source/drain region. The structure further includes a first intermetal dielectric (IMD) layer disposed below the first conductive feature, a second IMD layer disposed below the first IMD layer, and a plurality of memory devices disposed in the second IMD layer. The plurality of memory devices is electrically connected to the first conductive feature and are misaligned with the first source/drain region.

A further embodiment is a method. The method includes forming a plurality of source/drain regions over a substrate, forming an interconnect structure over the plurality of source/drain regions, flipping over the substrate, forming a first conductive feature on a backside of the substrate, depositing a first intermetal dielectric (IMD) layer on the first conductive feature, depositing a second IMD layer on the first IMD layer, depositing a third IMD layer on the second IMD layer, forming a second conductive feature through the first, second, and third IMD layer in a first region over the first conductive feature, and forming a memory device on the second conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a plurality of source/drain regions;
an interconnect structure disposed over the plurality of source/drain regions;
a backside interconnect structure disposed below the plurality of source/drain regions;
a first conductive feature disposed in the backside interconnect structure, wherein the first conductive feature is electrically connected to a first number of source/drain regions of the plurality of source/drain regions; and
a second number of memory devices disposed in the backside interconnect structure, wherein the memory devices are electrically connected to the first conductive feature, and the second number is different from the first number.

2. The semiconductor device structure of claim 1, wherein the first number is two, and the second number is four, six, or eight.

3. The semiconductor device structure of claim 1, further comprising a first intermetal dielectric (IMD) layer disposed between the first conductive feature and the memory devices, wherein the first conductive feature and the memory devices are in contact with the first IMD layer.

4. The semiconductor device structure of claim 3, further comprising second conductive features disposed in the first IMD layer, wherein the memory devices and the first conductive feature are electrically connected by the second conductive features.

5. The semiconductor device structure of claim 1, further comprising a substrate, wherein the plurality of source/drain regions are formed on a front side of the substrate, and the first conductive feature is in contact with a back surface of the substrate.

6. The semiconductor device structure of claim 5, further comprising one or more conductive contacts disposed in the substrate, wherein the first conductive feature is electrically connected to the first number of source/drain regions of the plurality of source/drain regions by the one or more conductive contacts.

7. The semiconductor device structure of claim 1, wherein three IMD layers are disposed between the first conductive feature and the memory devices.

8. The semiconductor device structure of claim 7, further comprising a third conductive feature disposed in the three IMD layers, wherein the third conductive feature electrically connects the first conductive feature and one of the memory devices.

9. A semiconductor device structure, comprising:
a first source/drain region disposed over a substrate, wherein the first source/drain region has a first width;
an interconnect structure disposed over the first source/drain region;
a first conductive feature disposed below a backside of the substrate, wherein the first conductive feature has a second width substantially greater than the first width, and the first conductive feature is electrically connected to the first source/drain region;
a first intermetal dielectric (IMD) layer disposed below the first conductive feature;
a second IMD layer disposed below the first IMD layer; and
a plurality of memory devices disposed in the second IMD layer, wherein the plurality of memory devices is electrically connected to the first conductive feature and are misaligned with the first source/drain region.

10. The semiconductor device structure of claim 9, further comprising a plurality of second conductive features disposed in the first IMD layer, wherein the plurality of memory devices is electrically connected to the first conductive feature by the plurality of second conductive features.

11. The semiconductor device structure of claim 9, further comprising:
a second source/drain region disposed over the substrate;
a first gate electrode layer disposed between the first and second source/drain regions;
a third source/drain region disposed over the substrate;
a second gate electrode layer disposed between the second and third source/drain regions;
a third gate electrode layer disposed adjacent the third source/drain region; and
a fourth source/drain region disposed over the substrate, wherein the third gate electrode layer is disposed between the third and fourth source/drain regions.

12. The semiconductor device structure of claim 11, wherein the plurality of memory devices comprises a first memory device, a second memory device, a third memory device, and a fourth memory device.

13. The semiconductor device structure of claim 12, wherein the first source/drain region is disposed between the first and second memory devices, and the second source/drain region is disposed between the third and fourth memory devices.

14. The semiconductor device structure of claim 12, wherein the first, second, third, and fourth source/drain regions each has a first side and a second side opposite the first side, the first sides of the first, second, third, and fourth source/drain regions are aligned, the second sides of the first, second, third, and fourth source/drain regions are aligned.

15. The semiconductor device structure of claim 14, wherein the first memory device is disposed on the first side of the first source/drain region, the second memory device is disposed on the second side of the second source/drain region, the third memory device is disposed on the first side of the third source/drain region, and the fourth memory device is disposed on the second side of the fourth source/drain region.

16. The semiconductor device structure of claim 15, wherein the first gate electrode layer is disposed between the first and second memory devices, the second gate electrode layer is disposed between the second and third memory devices, and the third gate electrode layer is disposed between the third and fourth memory devices.

17. A method, comprising:
forming a plurality of source/drain regions over a substrate;
forming an interconnect structure over the plurality of source/drain regions;
flipping over the substrate;
forming a first conductive feature on a backside of the substrate;
depositing a first intermetal dielectric (IMD) layer on the first conductive feature;
depositing a second IMD layer on the first IMD layer;
depositing a third IMD layer on the second IMD layer;
forming a second conductive feature through the first, second, and third IMD layer in a first region over the first conductive feature; and
forming a memory device on the second conductive feature.

18. The method of claim 17, further comprising forming a plurality of third conductive features in the first, second, and third IMD layers in a second region over the first conductive feature.

19. The method of claim 18, wherein the plurality of third conductive features comprises one or more first conductive vias formed in the first IMD layer, one or more conductive lines formed in the second IMD layer, and one or more second conductive vias formed in the third IMD layer.

20. The method of claim 18, wherein the plurality of third conductive features are formed before the forming of the second conductive feature.
